(19) United States
(12) Patent Application Publication
(10) Pub. No.: US 2014/0374808 A1
(43) Pub. Date: Dec. 25, 2014

(54) SEMICONDUCTOR COMPONENT WITH TRENCH GATE

(71) Applicant: PMDT Technologies GmbH, Siegen (DE)

(72) Inventors: Matthias Franke, Haiger (DE); Nils Friedrich, Siegen (DE); Jens Prima, Siegen (DE)

(73) Assignee: PMDT Technologies GmbH, Siegen (DE)

(21) Appl. No.: 14/365,047

(22) PCT Filed: Dec. 11, 2012
(86) PCT No.: PCT/EP2012/075047

§ 371 Date: Jun. 12, 2014

(30) Foreign Application Priority Data
Dec. 13, 2011 (DE) 10 2011 056 369.5

(51) Int. Cl. H01L 31/112; H01L 27/146

(52) U.S. Cl. CPC H01L 31/1126; H01L 27/1461
USPC 257/290

(57) ABSTRACT

The present invention relates to a semiconductor component (1) having a photosensitive semiconductor layer (2), wherein the photosensitive semiconductor layer (2) is doped with a first doping density (D1) of a first conduction type which brings about an effective conversion of electromagnetic radiation penetrating into the semiconductor layer (2) into electrical charge carriers, having at least two modulation gates (4A, 4B) which are arranged at a mutual spacing and are each formed by a trench gate extending from a surface (3) of the semiconductor layer (2) and perpendicular to this surface (3) into the semiconductor layer (2), and having at least two readout diodes (5A, 5B) arranged at a mutual spacing and near the surface (3) between the two modulation gates (4A, 4B). In order to provide a semiconductor component for distance detection having improved characteristics with regard to sensitivity and resolution, the invention proposes that a separating implant (6) be inserted into the semiconductor layer (2) between the two readout diodes (5A, 5B), said implant having the same conduction type as the semiconductor layer (2), but having a second, higher doping density (D2).

The present invention concerns a semiconductor component having a photosensitive semiconductor layer, wherein the photosensitive semiconductor layer has a doping with a first doping density D1 of a first conductivity type which causes effective conversion of electromagnetic radiation penetrating into the semiconductor layer into electrical charge carriers, at least two mutually spaced modulation gates which are each formed by a trench gate extending from a surface of the semiconductor layer and perpendicularly to said surface into the semiconductor layer, and at least two read-out diodes arranged at a spacing relative to each other and near the surface between the two modulation gates.

Semiconductor components having a photosensitive semiconductor layer in which incident electromagnetic radiation is converted into electrical charge carrier's as well as two modulation gates and two read-out diodes are used in transit time measurement of electromagnetic signals. The measured transit time is used to determine the distance of objects. For that purpose intensity-modulated light beams are detected, which were reflected by corresponding objects, and phase shifts in relation to the frequency of the signal source are determined. For that purpose the modulation gates are for the most part arranged on the semiconductor layer. Such an arrangement of the modulation gates over the semiconductor layer results in a layer structure which leads to changes in the refractive index and reflection losses resulting therefrom in respect of the incident light beams. Such reflection losses can be effectively minimised only at a high level of complication and expenditure, due to the structure involved. In addition the sensitivity of the component is dependent on the extent and the strength of the applied electrical field in the semiconductor layer. That field influences the free charge carriers generated in the semiconductor layer and guides them in the direction of the read-out diodes. Essentially, the electrical field is determined or limited by the modulation voltage applied to the modulation gates and the read-out voltage at the read-out diodes and the substrate doping.

US 20090244514 A1 which the present invention takes as its basic starting point as the closest state of the art proposes using modulation gates in the form of trench gates. In accordance with US 20090244514 A1 such a structure reduces the area claimed by the photogates on the photosensitive semiconductor layer, and that leads to a reduction in the screening effect.

Taking that state of the art as its starting point the object of the present invention is to provide a semiconductor component for distance measurement having improved properties in regard to sensitivity and resolution.

That object is attained in that introduced into the semiconductor layer between the two read-out diodes is a separating implant which is of the same conductivity type as the semiconductor layer but with a second higher doping density D2.

In particular the following doping densities are preferred when using silicon for the semiconductor layer, separating implant and substrate: D1 in the range of between about 10¹³ and about 10¹⁴, D2 of between about 10¹⁶ and about 10¹⁷ and D3 of between about 10¹⁸ and about 10¹⁹.

A read-out voltage is applied at the read-out diodes for reading out the charge carriers generated by photons in the semiconductor material. A respective space charge zone is produced in the semiconductor layer by that voltage in the region of the read-out diodes. A separating implant introduced into the semiconductor layer between the read-out diodes prevents the space charge zones from laterally penetrating between the two read-out diodes. By virtue of that separation by means of separating implants, comparatively high voltages can be applied at the read-out diodes even in the case of a spatially highly compact structure for the semiconductor components A more compact structure in turn allows faster read-out of free charge carriers by virtue of shorter paths. At the same time the stronger electrical fields applied to influence the charge carriers can completely penetrate the semiconductor layers The extent of the space charge zones, caused by diffusion of majority charge carriers, is dependent on the doping density. The higher the doping density is the correspondingly narrower is the space charge zone as the higher density at remaining lattice ions involves the production of a stronger electrical field which counteracts diffusion. Doping of the separating implant with the same conductivity type as the semiconductor layer however with a higher doping density leads to the space charge zones in the separating implant and the semiconductor layer being of extents of differing magnitudes. As a consequence of a reduced extent of the space charge zones in the region of a higher doping the separating implant effectively prevents lateral penetration of the space charge zone between the read-out diodes, whereby interference effects are minimised and sensitivity is increased and thus operability of the semiconductor component is guaranteed even when a compact structure is involved. The use of the same material for the semiconductor layer and the separating implant is to be recommended, in which case the two components only differ by the doping density. In that respect it is also desirable if the separating implant extends in a vertical direction deeper into the semiconductor layer than into the read-out diodes whereby the lateral separation of the two diodes is improved. Advantageously the semiconductor layer and/or the separating implant comprise silicon of the p-conductivity type, in which case the free, to be read-out . . . . It will be appreciated that, even if the description herein relates predominantly to electrons as minority charge carriers, instead thereof holes could also be the minority charge carriers, insofar as for example the semiconductor layer and the separating implant comprise a material of n-conductivity type.

In an embodiment the semiconductor layer is arranged on a semiconductor substrate which is of the same conductivity type but having a doping with a third doping density D3 which is higher than the first and second doping densities. Vertical delimitation of the space charge zones and accordingly a constant base potential in respect of the read-out voltage are ensured by that highly doped substrate which for example is held at a constant potential, even in the case of deep depletion of the semiconductor layer, that is to say a complete vertical extent of the space charge zones through the low-doped semiconductor layer. That permits an, effective potential gradient in the vertical direction, which in the entire semiconductor region between the modulation gates passes free charge carriers which were produced by penetrating photons to the read-out diodes.

In an embodiment the doping densities D1, D2 and D3 respectively differ by at least one order of magnitude. Such component-wise differences in the doping density of at least one order of magnitude can ensure an effective geometrical extent of the space charge zones around the read-out diodes through the semiconductor layer, wherein that space charge zone, with the exception of the separating implant, extends substantially through the entire semiconductor layer between the modulation gates.

A desirable embodiment is one in which the semiconductor substrate has a contacting means, wherein the semiconductor substrate can be held at a first potential by means of the contacting means. A read-out voltage results from the potential difference between the potentials of the read-out diodes and φ_{S} as the base potential. As a consequence of that read-out voltage there is a vertical potential gradient which penetrates through the entire semiconductor layer and by which free charge carriers are moved to the read-out diodes. A modulation voltage is additionally applied at the semiconductor layer by means of the modulation gates formed by trench gates. That modulation voltage produces a alternating horizontal potential gradient. The charge carriers produced in the semiconductor layer are moved alternately to one of the two read-out diodes by that fluctuating gradient. That operative principle of the alternate displacement of free charge carriers to one of the two read-out diodes by means of the superimpositioning of a constant vertical potential gradient with an alternating horizontal potential gradient is referred to herein as a ‘windshield wiper principle’. If the variation in intensity in respect of time of the penetrating electromagnetic voltage and thus the variation in respect of time of the number of charge carriers produced is uncorrelated with the frequency of the modulation voltage then as a statistical mean in general approximately an equal number of charge carriers respectively pass to both read-out diodes. If however at least a part of the radiation involves an intensity frequency which is correlated with the frequency of the modulation voltage then as a statistical mean this generally involves a charge difference between the read-out diodes.

In an embodiment according to the invention the trench gates respectively comprise a channel extending from the surface of the semiconductor layer and perpendicularly to said surface into the semiconductor layer, wherein the channel walls are lined with an electrically insulating layer and an electrically conducting material is arranged in the channel. The vertical extent of the modulation gates in the form of trench gates makes it possible to produce a strong electrical field which reaches deeply in the vertical direction and by which free charge carriers are influenced by the potential gradient of the modulation voltage even in deep regions of the semiconductor layer. At the same time the arrangement of the modulation gates in the semiconductor layer avoids a reduction in the amount of light which is coupled in through structures disposed above the layer, in particular polysilicon or metal structures. That opens up the possibility of independent adaptation of light coupling-in into the semiconductor layer, whereby a very high level of quantum efficiency can be achieved. In addition the vertical trench gates with the read-out diodes disposed therebetween afford the advantage that, when a plurality of semiconductor components according to the invention are arranged in mutually juxtaposed relationship, effective shielding in relation to crosstalk of the photocharge carriers between the individual semiconductor components is implemented. Such effective shielding is particularly advantageous in the case of a common integral semiconductor layer connecting all semiconductor components.

Modulation gates according to the invention are for example etched BO in a semiconductor layer comprising doped silicon. The channel walls are than oxidised or a thin oxide layer is deposited at the walls. The insulating layer resulting therefrom at the channel walls desirably consists of silicon oxide. The remaining internal space in the channel is partially or completely filled with an electrically conducting material, preferably with polysilicon, and contacted in the region of the surface of the semiconductor layer. Other electrically conducting materials like for example tungsten can however also be considered for filling the channel.

In an embodiment the aspect ratio of the trench gates of depth to breadth is at least 5:1, preferably at least 10:1, but at most 100:1. An aspect ratio of between about 15:1 and about 25:1 is particularly preferred, That ensures a deep vertical extent for the modulation gates and thus the potential gradient of the modulation voltage with at the same time a compact and efficient structure as the modulation gates can be very narrow and thus take up only a small part of the surface area In that case the thickness of the semiconductor layer is between about 5 ∥m and about 50 μm, for example between about 5 μm and about 20 μm and in particular between about 8 μm and about 15 μm.

In an embodiment of the invention the read-out diodes are pn-diodes, wherein the pn-diodes each have a highly doped semiconductor implant which is introduced into the semiconductor layer and which is of a fourth doping density D4 of a second conductivity type. By virtue of the different conductivity types of semiconductor implant and semiconductor layer or separating implant respectively there is a space charge zone in the form of a pn-junction as a consequence of diffusion of the respective majority charge carriers in the interface region between those components. When a read-out voltage is applied to the read-out diodes and at the same time a modulation voltage is applied to the modulation gates those voltages alternately influence the optically generated charge carriers in the same region of the semiconductor layer. The field direction operative for the free charge carriers in the semiconductor layer between the modulation gates is afforded by vectorial addition of the vertical field, that is to say the read-out field, and the lateral field, that is to say the modulation field. Accordingly the contrast of the semiconductor component, that is to say the ratio of the sensitivity to electromagnetic radiation with a modulated intensity frequency to the sensitivity to radiation with a random intensity frequency, is determined by the geometrical dimensions of the arrangement, that is to say the thickness of the semiconductor layer and the spacing between the modulation gates, as well as the applied read-out and modulation voltages. The superimpositioning of the electrical fields in accordance with a ‘windshield wiper principle’ is effected by virtue of the vertical extent of the modulation gates in a comparatively large cross-section of the semiconductor layer through which the electrical fields completely pass. In that way troublesome charge carrier diffusion upon measurement is minimised and a high level of contrast is achieved even for high modulation frequencies. The low doping level of that layer ensures sufficiently deep penetration of the electrical field and related thereto effective separation of the photocharge carriers.

According to an embodiment a respective separation gate is arranged between modulation gate and adjacent read-out diode. Such a separation gate minimises cross-coupling of the modulation signal of the modulation gates on to the read-out diodes. That minimisation of cross-coupling makes it possible to increase the modulation voltage applied at the modulation gates and thus to improve both the response speed and also the sensitivity of the component.

This separation gate including the variants and additions described in relation to separation gates can obviously also be advantageously used to avoid cross-coupling between modulation gates and read-out diodes when there is no separating implant between the read-out diodes.

Desirably in an embodiment the separation gates are electrically insulated from the photosensitive semiconductor layer, the modulation gates and the read-out diodes. The electrical insulation ensures that the separation gates do not interfere with the read-out of the photoelectrons by the read-out diodes. Desirably the insulation is afforded by means of an insulating layer of silicon oxide.

An embodiment according to the invention of the semiconductor component is of such a configuration that the semiconductor layer can be lit by that surface at which the read-out diodes and the separating implant are arranged. Alternatively the semiconductor layer which is sensitive to the radiation can also be lit by the semiconductor substrate on which the semiconductor layer is arranged (backlighting). It will be appreciated that this requires the use of a substrate which is sufficiently transparent for the radiation involved (backdiluted). The substrate-side lighting permits even more complex structures near the surface of the semiconductor substrate, which in the case of surface-side lighting would lead to a severe shadowing.

In an embodiment the semiconductor substrate is held at a first potential while the difference between the potentials of the modulation gates varies in accordance with a modulation frequency by the potential of the semiconductor substrate. That results in the production of a horizontal potential gradient alternating in accordance with the modulation frequency in the semiconductor layer between the modulation gates. Consequently the free charge carriers produced by the penetrating electromagnetic radiation are moved alternately in accordance with the modulation frequency in the lateral direction to one of the two read-out diodes.

A method of operating a semiconductor component according to the invention is desirable, in which an equal constant read-out voltage is respectively applied at the read-out diodes and the modulation voltage at the modulation gates varies in push-pull manner. That modulation voltage produces in the semiconductor layer an electrical field which changes in respect of time in the horizontal direction. The number of charge carriers produced in the semiconductor layer is directly proportional to the intensity of the penetrating electromagnetic radiation. Those charge carriers can be passed either to the one read-out diode or the other by virtue of the potential gradient, in dependence on the applied modulation voltage. Charge carriers produced by uncorrelated radiation are generally distributed as a statistical mean in equal parts on both read-out diodes. The situation is different if a light signal has a fixedly predetermined intensity-modulated frequency which is correlated with the modulation frequency of the modulation gates. In that case, by virtue of the correlated potential gradient caused by the modulation voltage, the charge carriers are generally predominantly guided to one of the two read-out diodes. The phase shift between applied modulation voltage and modulated intensity frequency of the received light signal can be ascertained from the difference of the charge amounts respectively read out by the two read-out diodes. If the phase relationship between modulation voltage and light signal upon the emission thereof as well as the relative position of the emitter with respect to the semiconductor component according to the invention are known then the ascertained phase shift represents a measurement in respect of the distance of a body reflecting the light signal.

In an embodiment the read-out and modulation voltages are so adjusted that a deep vertical field penetration is produced in the semiconductor layer between the trench gates. Such a deep field penetration leads to complete depletion of the low-doped semiconductor layer, that is to say the space charge zones of the read-out diodes, with the exception of the separating implant, extend over the entire intermediate space between the modulation gates. Operation in the condition of complete depletion permits fast and quantitatively precise response on the part of the semiconductor component to penetrating photons or the charge carriers which are produced thereby and which substantially represent the sole free charge carriers in the photosensitive region.

In an embodiment according to the invention the circuitry of the read-out diodes permits direct read-out of the photocurrents produced in the semiconductor layer. In that case the distribution which varies in respect of time of the charge carriers to the read-out diodes can be directly understood. In particular the variation in respect of time of such charge carrier distributions which are based on high-frequency intensity modulation and therefore change quickly can be rapidly detected or precisely resolved. Direct read-out of the photocurrents without an accumulative intermediate step therefore ensures precise distance detection even with high-frequency modulation voltages. High-frequency modulation voltages of that kind are advantageous in particular for the detection of rapidly moving objects which quickly change their distance by virtue of their high speed. As in that case, as a consequence of rapid changes in position, only comparatively short measurement intervals are available, a rapid response characteristic with at the same time a high level of sensitivity, as are afforded by the present invention, are advantageous, In addition direct read-out of the read-out diodes affords the advantage that the diodes do not have to serve as integration capacitors and accordingly can be of a small cross-section so that they require correspondingly little pixel area.

Desirably a pixel for distance measurement has a photosensitive pixel surface with at least one semiconductor component as set forth in one of claims 1 through 9. With the arrangement of a semiconductor component according to the invention in a pixel the circuitry interconnection of the individual components is effected by suitable read-out electronic means of the pixel. Such a pixel makes it possible to ascertain an linage point which includes specific spot distance information on the basis of the difference signal between the two read-out diodes and/or specific spot intensity information based on the corresponding sum

According to the invention a sensor for three-dimensional image capture has a plurality of pixels arranged in mutually juxtaposed relationship as set forth in claim 13, as well as an imaging optical system for the projection of incident electromagnetic radiation en to a sensor surface formed by the photosensitive pixel surfaces. By means of such a sensor according to the invention it becomes possible to put together a plurality of image points based on the measurement signals of a plurality of pixels according to the invention by means of a sensor-internal electronic evaluation system to give a three-dimensional overall image. In that respect it is desirable if the sensor also has an emitter for emitting intensity-modulated electromagnetic radiation. If that intensity-modulated radiation is reflected back to the sensor by an ambient object the respective corresponding distance of the imaged object points can be ascertained from the phase shift between reflected radiation and a frequency, correlated with the intensity frequency of the emitter, of the modulation voltage at the modulation gates, for individual image points.

Further advantages, features and possible uses of the present invention will be apparent from the description hereinafter of preferred embodiments and the related Figures in which:

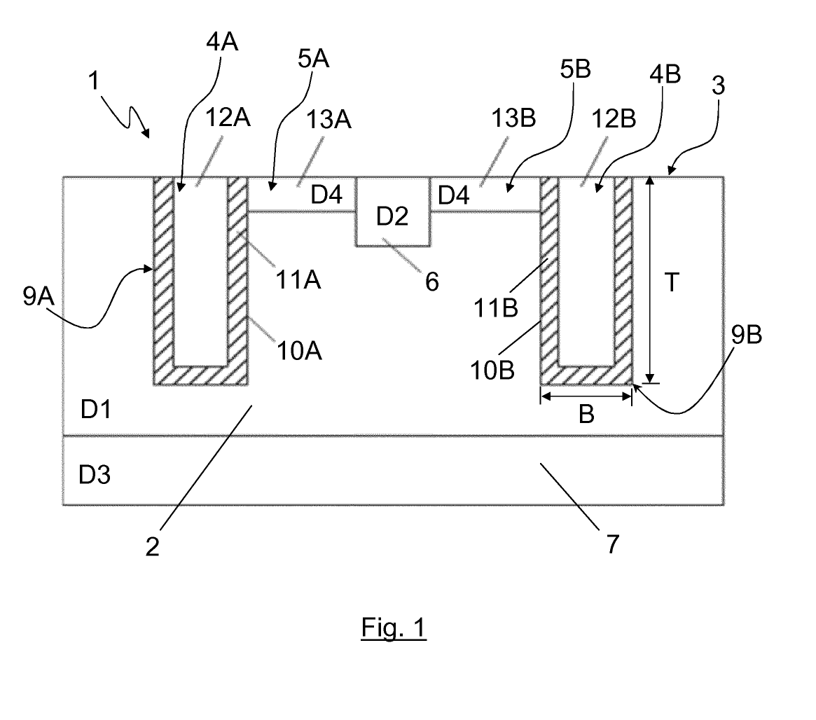

FIG. 1 shows a semiconductor component according to the invention with separating implant,

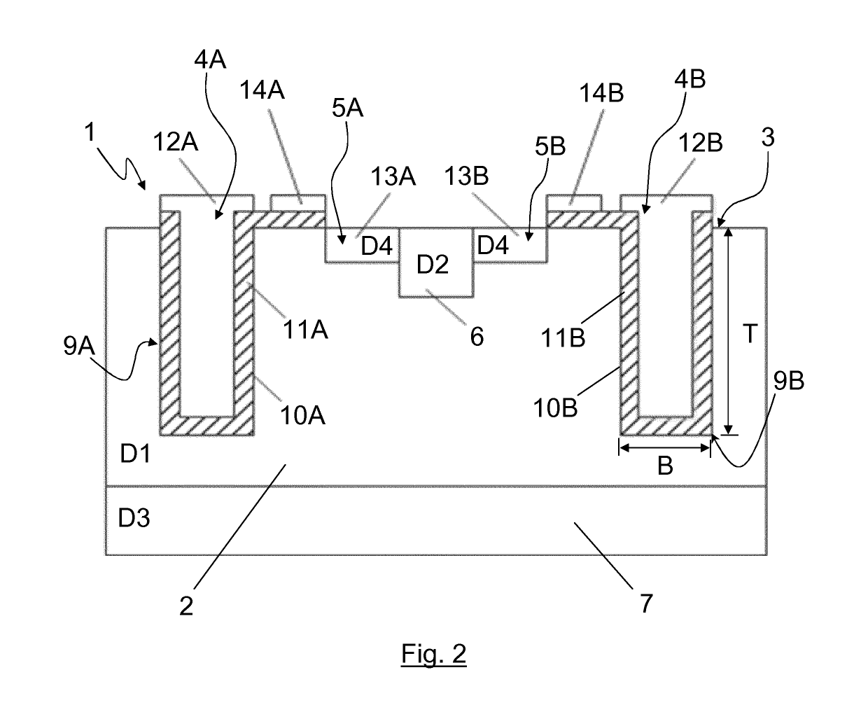

FIG. 2 shows a semiconductor component according to the invention with separation gates, and

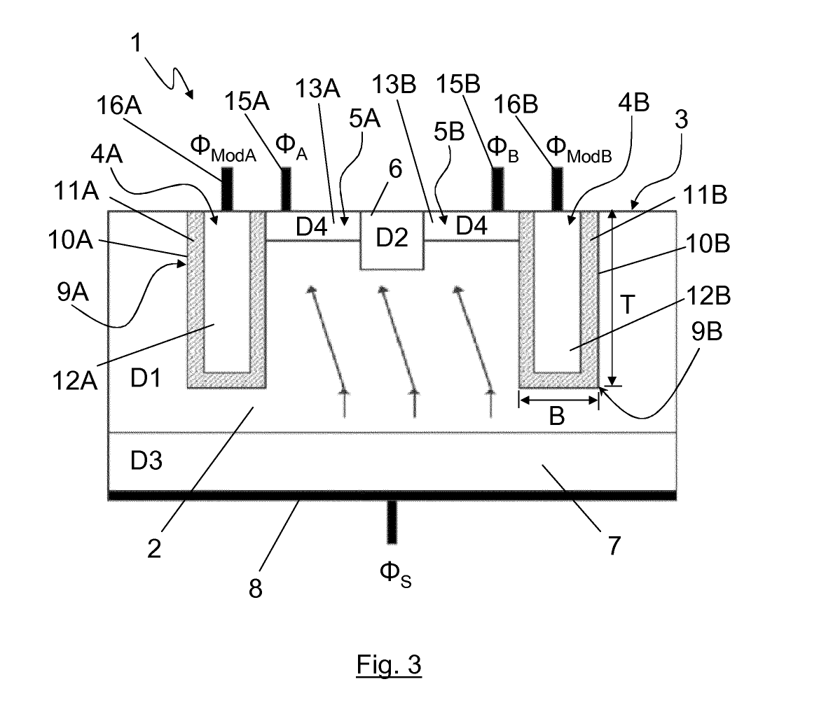

FIG. 3 shows a diagrammatic view of the electrical field direction in the semiconductor component of FIG. 1.

FIG. 1 shows a cross-section perpendicularly to the longitudinal direction of the channels 9A, 98 through a semiconductor component 1 according to the invention with separating implant 6. It is possible to see an epitaxial photosensitive semiconductor layer 2 arranged on a semiconductor substrate 7. The semiconductor layer 2 comprises a low doped silicon material with a doping density D1 of p-conductivity type, The substrate 7 also comprises a silicon material of the p-conductivity type, but with a high doping density D3. Two modulation gates 4A, 4B in the form of trench gates with channels 9A, 9B extend into the semiconductor layer 2 from the surface 3 thereof and perpendicularly thereto. In the illustrated embodiment the two channels 9A, 9B pass through the semiconductor substrate 2 parallel to each other. Those trench gates 4A, 4B are each of the same elongated rectangular cross-section of a depth T and a breadth B. The inside wails 10A, 10B of the channels 9A, 9B are lined with an insulating layer 11A, 11B comprising silicon oxide. The remaining internal space in the channels of rectangular cross-section is filled with polysilicon. Arranged between the two modulation gates 4A, 4B in the region of the surface of the semiconductor layer 2 are two mutually spaced read-out diodes 5A, 5B which each have a highly doped semiconductor implant 13A, 13B of the n-conductivity type. Each of those semiconductor implants 13A, 13B respectively directly adjoins the channels 9A, 9B of a modulation gate 4A, 4B respectively. The space between the two read-out diodes 5A, 5B is completely billed by a separating implant 6 introduced into the semiconductor layer 2. That separating layer 2 extends in a vertical direction further into the semiconductor layer 2 than the semiconductor implants 13A, 13B of the read-out diodes 5A, 5B. In that respect the extent of the separating implant 6 in a vertical direction downwardly is approximately double the length compared to the read-out diodes 5A, 5B. The separating implant 6 comprises a highly doped silicon material of the p-conductivity type. The electrical contacting means of the individual components are not shown, that is to say the contacting means 15A, 15B of the two read-out diodes 5A, 5B, the contacting means 16A, 16B of the two modulation gates 4A, 4B and the contacting means of the semiconductor substrate 8.

FIG. 2 shows a cross-section perpendicularly to the longitudinal direction of the channels 9A, 9B through a semiconductor component 1 according to the invention with separating implant 6 and two separation gates 14A, 14B. The semiconductor component 1 again comprises a low-doped epitaxial silicon layer 2 of p-conductivity type, which is applied to a highly doped silicon substrate 7 also of the p-conductivity type. Two channels 9A, 9B extending parallel through the semiconductor layer 2 extend from the surface of the semiconductor layer 2 perpendicularly to the surface 3 in a downward direction. The inside walls 10A, 10B of the channels 9A, 9B are lined with an insulating layer 11A, 11B of silicon oxide. In that case the insulating layers 11A, 11B respectively project beyond the surface 3 of the semiconductor layer 2 and extend towards each other between the trench gates 4A, 4B on the surface 3 of the semiconductor layer 2. Those portions of the insulating layer 11A, 11B on the surface 3 are spaced from each other in such a way that, in the horizontal direction, a free uncoated region is formed between them. Disposed beneath that uncoated region are two read-out diodes 5A, 5B in the semiconductor layer 2, between which there is a separating implant 6. The two read-out diodes 5A, 5B respectively have a semiconductor implant 13A, 13B comprising a highly doped semiconductor material of the n-conductivity type. Arranged between the semiconductor implants 13A, 13B and flush thereto is the separating implant 6 comprising highly doped silicon of the p-conductivity type. The separating implant 6 extends approximately twice as far as the two semiconductor implants 13A, 13B in a vertical direction into the silicon layer 2. In this embodiment the two semiconductor implants 13A, 13B are respectively spaced from the channel wails 10A, 10B. In this case the spacing from the channel walls 10A, 10B is respectively the same as the length of the extent of the insulating layer 11A, 11B on the surface 3 of the semiconductor layer 2. The remaining space inside the channels 9A, 9B is filled with polysilicon. Arranged between the two modulation gates 4A, 4B on the insulating layer 11A, 11B which extends above the semiconductor surface 3 is a respective separation gate 14A, 14B. The separation gates 14A, 14B respectively end horizontally at the same height as the insulating layer 11A, 11B. In this case the separation gates 14A, 14B are spaced from the modulation gates 4A, 4B of polysilicon. The drawing does not show the electrical contacting means of the individual components, that is to say the contacting means 15A, 15B of the two read-out diodes 5A, 5B, the contacting means 16A, 16B of the two modulation gates 4A, 4B and the contacting means of the semiconductor substrate 8.

FIG. 3 shows a cross-section perpendicularly to the longitudinal direction of the channels 9A, 9B through the semiconductor component according to the invention as shown in FIG. 1, in which the field direction of the electrical field between the modulation dates 4A, 4B is diagrammatically shown. That field, represented by three long arrows extending inclinedly upwardly and to the left in the direction of the read-out diode 5A, is composed at the height of the modulation gates 4A, 4B from the superimpositioning of the lateral modulation voltage V_{Mod} and the vertical read-out voltage V_{A}. In the region beneath the modulation gates 4A, 4B it is substantially the vertical read-out voltage V_{A}, represented by three short vertical arrows, that dominates. The resulting field direction vividly recalls a windshield wiper. In the illustrated case the silicon substrate 7 is kept at a constant potential φ_{S} by way of a contacting means 8. Preferably the substrate 7 is grounded by way of the contacting means 8, that is to say φ_{S}=0 volts. In the meantime the read-out diodes 5A and 5B are respectively held at the same positive potential φ_{A}=φ_{B}>0 by way of the contacting means 15A and 15B. Accordingly the same positive read-out voltage V_{A} which derives from the difference between the potentials φ_{A} and φ_{S} respectively and the potential φ_{S} that is to say, V_{A}=φ_{A}−φ_{S}=φ_{B}−φ_{S}>0 volts, occurs at both read-out diodes 5A, 5B. The modulation gates 4A and 4B are respectively held at a potential φ_{ModA} and φ_{ModA} by way of the contacting means 16A and 16B. At the illustrated moment in time moreover the potential φ_{modA} of the modulation gate 4A which varies in time in push-pull relationship with the potential φ_{ModB} of the modulation gate 4B is just greater than φ_{ModB}, that is to say φ_{ModA}>φ_{ModB}. In accordance with the ‘windshield wiper principle’ the electrical field direction therefore faces towards the left upwardly towards the read-out diode 5A. Thus photoelectrons produced with the illustrated instantaneous orientation of the electrical field are read out almost exclusively by way of the read-out diode 5A.

For the purposes of the original disclosure it is pointed out that all features as can be seen by a man skilled in the art from the present description, the drawings and the claims, even if they are described in specific terms only in connection with certain other features, can be combined both individually and also in any combination with others of the features or groups of features disclosed here insofar as that has not been expressly excluded or technical aspects make such combinations impossible or meaningless. A comprehensive explicit representation of all conceivable combinations of features and emphasis of the independence of the individual features from each other is dispensed with here only for the sake of brevity and readability of the description.

### LIST OF REFERENCES

1 semiconductor component

2 photosensitive semiconductor layer

3 surface of the photosensitive semiconductor layer

4A, 4B modulation gate A and G respectively

5A, 5B read-out diode A and B respectively

6 separating implant

7 semiconductor substrate

8 contacting of the semiconductor substrate

9A, 9B channel

10A, 10B channel wall

11A, 11B insulating layer

12A, 12B electrically conducting material

13A, 13B semiconductor implant

14A, 14B separation gate

15A, 15B contacting means of the read-out diode

16A, 16B contacting means of the modulation gate

D1 first doping density

D2 second doping density

D3 third doping density

D4 fourth doping density

T channel depth

B channel breadth

φ_{A}, φ_{B} potential of the read-out diode A and B respectively

φ_{ModA}, φ_{ModB} potential at the modulation gate A and B respectively

φ_{S} substrate potential

V_{A} read-out voltage

V_{Mod} modulation voltage

1. A semiconductor component (1) having a photosensitive semiconductor layer (2), wherein the photosensitive semiconductor layer (2) has a doping with a first doping density (D1) of a first conductivity type which causes effective conversion of electromagnetic radiation penetrating into the semiconductor layer (2) into electrical charge carriers,
at least two mutually spaced modulation gates (4A, 4B) which are each formed by a trench gate extending from a surface (3) of the semiconductor layer (2) and perpendicularly to said surface (3) into the semiconductor layer (2), and
at least two read-out diodes (5A, 5B) arranged at a spacing relative to each other and near the surface (3) between the two modulation gates (4A, 4B),
characterised in that introduced into the semiconductor layer (2) between the two read-out diodes (5A, 5B) is a separating implant (6) which is of the same conductivity type as the semiconductor layer (2) but with a second higher doping density (D2).

2. A semiconductor component (1) as set forth in claim 1 characterised in that the semiconductor layer (2) is arranged on a semiconductor substrate (7) which is of the same conductivity type but having a doping with a third doping density (D3) which is higher than the first (D1) and second (D2) doping densities.

3. A semiconductor component (1) as set forth in claim 2 characterised in that the doping densities (D1, D2 and D3) respectively differ by at least one order of magnitude.

4. A semiconductor component (1) as set forth in claim 3 characterised in that the semiconductor substrate (7) has a contacting means (8), wherein the semiconductor substrate (7) can be held at a first potential (φ_{S}) by means of the contacting means (8).

5. A semiconductor component (1) as set forth in claim 1 characterised in that the trench gates (4A, 4B) respectively comprise a channel (9A, 9B) extending from the surface (3) of the semiconductor layer (2) and perpendicularly to said surface (3) into the semiconductor layer (2), wherein the channel walls (10A, 10B) are lined with an electrically insulating layer (11A, 11B) and an electrically conducting material (12A, 12B) is arranged in the channel (9A, 9B).

6. A semiconductor component (1) as set forth in claim 1 characterised in that the aspect ratio of the trench gates (4A, 4B) of depth (T) to breadth (B) is at least 5:1.

7. A semiconductor component (1) as set forth in claim 1 characterised in that the read-out diodes (5A, 5B) are pn-diodes, wherein the pn-diodes each have a highly doped semiconductor implant (13A) which is introduced into the semiconductor layer (2) and which is of a fourth doping density (D4) of a second conductivity type.

8. A semiconductor component (1) as set forth in claim 1 characterised in that a respective separation gate (14A, 14B) is arranged between a modulation gate (4A, 4B) and an adjacent read-out diode (5A, 5B).

9. A semiconductor component (1) as set forth in claim 8 characterised in that the separation gates (14A, 14B) are electrically insulated from the photosensitive semiconductor layer (2), the modulation gates (4A, 4B) and the read-out diodes (5A, 5B).

10. A method of operating a semiconductor component (1) as set forth in claim 1 characterised in that the semiconductor substrate (7) is held at a first potential (φ_{S}) while the difference between the potentials (φ_{ModA}, φ_{ModB}) of the modulation gates (4A, 4B) varies in accordance with a modulation frequency by the potential (φ_{S}) of the semiconductor substrate (7).

11. A method as set forth in claim 10 characterised in that an equal constant read-out voltage (V_{A}) is respectively applied at the read-out diodes (5A, 5B) and the modulation voltage (V_{Mod}) at the modulation gates (4A, 4B) varies in push-pull manner.

12. A method as set forth in claim 11 characterised in that the circuitry of the read-out diodes (5A, 5B) permits direct read-out of the photocurrents generated in the semiconductor layer (2).

13. A pixel for distance measurement characterised in that it has a photosensitive pixel surface having at least one semiconductor component (1) as set forth in claim 1.

14. A sensor for three-dimensional image capture characterised in that it has a plurality of mutually juxtaposed pixels as set forth in claim 13 and an imaging optical system for the projection of incident electromagnetic radiation on to a sensor surface formed by the photosensitive pixel surfaces.

15. A method as set forth in claim 10 characterised in that the circuitry of the read-out diodes (5A, 5B) permits direct read-out of the photocurrents generated in the semiconductor layer (2).

16. A semiconductor component (1) as set forth in claim 2 characterised in that the semiconductor substrate (7) has a contacting means (8), wherein the semiconductor substrate (7) can be held at a first potential (φ_{S}) by means of the contacting means (8).

17. A semiconductor component (1) as set forth in claim 1 characterised in that the aspect ratio of the trench gates (4A, 4B) of depth (T) to breadth (B) is at least 10:1.

18. A semiconductor component (1) as set forth in claim 1 characterised in that the aspect ratio of the trench gates (4A, 4B) of depth (T) to breadth (B) is at most 100:1.
